(19) United States
(12) Patent Application Publication
(10) Pub. No.: US 2012/0199886 A1
(43) Pub. Date: Aug. 9, 2012

(54) SEALED AIR GAP FOR SEMICONDUCTOR CHIP

(75) Inventors: David V. Horak, Essex Junction, VT (US); Elbert E. Huang, Carmel, NY (US); Charles W. Koburger, III, Delmar, NY (US); Douglas C. La Tulipe, JR., Guilderland, NY (US); Shom Ponoth, Clifton Park, NY (US)

(73) Assignee: INTERNATIONAL BUSINESS MACHINES CORPORATION, Armonk, NY (US)

(21) Appl. No.: 13/020,107

(22) Filed: Feb. 3, 2011

(51) Int. Cl. H01L 29/772; H01L 21/336

(52) U.S. Cl. 257/288; 438/287; 438/299; 257/E29.242; 257/E21.409

(57) ABSTRACT

A semiconductor chip, including a substrate; a dielectric layer over the substrate; a gate within the dielectric layer, the gate including a sidewall; a source and a drain in the substrate adjacent to the gate; a tapered contact contacting a portion of one of the source or the drain; and a sealed air gap between the sidewall and the contact.

### CROSS-REFERENCE TO RELATED APPLICATION

This application is related in some aspects to commonly owned patent application Ser. No. 12/914,132, entitled “SEALED AIR GAP FOR SEMICONDUCTOR CHIP”, assigned attorney docket number BUR921000078US1, filed on Nov. 10, 2010, the entire contents of which are herein incorporated by reference.

### FIELD OF THE INVENTION

The present invention relates generally to forming a sealed air gap in semiconductor chips. In particular, the present invention provides a semiconductor chip and method for forming sealed air gaps in semiconductor chips by removing sacrificial spacers adjacent to gates after contact formation.

### BRIEF SUMMARY OF EMBODIMENTS OF THE INVENTION

Semiconductor chips continue to be used in an increasing variety of electronic devices. Simultaneously, the trend in semiconductor chips is to create greater functional capacity with smaller devices. As a result, forming more efficient semiconductor chips requires that the components of semiconductor chips operate more efficiently.

Spacers including silicon nitride formed adjacent to gate sidewalls have a relatively high dielectric constant resulting in gate-to-diffusion and gate-to-contact parasitic capacitances that increase power consumption and reduce performance of semiconductor chips. Spacers including oxide have lower parasitic capacitance but do not stand up well to middle-of-line (MOL) processing. Replacing nitride spacers with oxide results in a lower parasitic capacitance.

Air gaps formed adjacent to gate sidewalls provide the lowest possible dielectric constant with the lowest parasitic capacitance.

### BRIEF SUMMARY OF EMBODIMENTS OF THE INVENTION

A first aspect of the invention includes a semiconductor chip, comprising: a substrate; a dielectric layer over the substrate; a gate within the dielectric layer, the gate including a sidewall; a source and a drain in the substrate adjacent to the gate; a tapered contact contacting a portion of one of the source or the drain; and a sealed air gap between the sidewall and the contact.

A second aspect of the invention includes a method, comprising: forming a gate over a substrate; forming a source and a drain in the substrate and adjacent to the gate; forming a sacrificial spacer adjacent to the gate; forming a first dielectric layer about the gate and the sacrificial spacer; forming a tapered contact through the first dielectric layer and about the sacrificial spacer to one of the source or the drain; substantially removing the sacrificial spacer, wherein a space is formed between the gate and the tapered contact; and forming a sealed air gap in the space by depositing a second dielectric layer over the first dielectric layer.

A third aspect of the invention includes a method, comprising: forming a gate over a substrate; forming a source and a drain in the substrate adjacent to the gate; forming a sacrificial spacer adjacent to a sidewall of the gate; forming a first dielectric layer about the gate and the sacrificial spacer; forming a tapered contact through the first dielectric layer and about the sacrificial spacer, wherein the tapered contact includes a first side contacting a portion of one of the source or the drain, a second side about the sacrificial spacer, and a third side opposite from and wider than the first side; substantially removing the sacrificial spacer to form a space between the gate and the tapered contact; and forming a sealed air gap in the space by depositing a second dielectric layer over the first dielectric layer.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a cross-section view of one embodiment of a step in processing of a semiconductor chip in accordance with this invention.

FIG. 2 shows a cross-section view of one embodiment of a step in processing of semiconductor chip in accordance with this invention.

FIG. 3 shows a cross-section view of one embodiment of a step in processing of semiconductor chip in accordance with this invention.

FIG. 4 shows a cross-section view of one embodiment of a step in processing of semiconductor chip in accordance with this invention.

FIG. 5 shows a cross-section view of one embodiment of a step in processing of semiconductor chip in accordance with this invention.

FIG. 6 shows a cross-section view of one embodiment of a step in processing of semiconductor chip in accordance with this invention.

FIG. 7 shows a cross-section view of one alternative embodiment of a step in processing of a semiconductor chip in accordance with this invention.

FIG. 8 shows a cross-section view of one embodiment of a step in processing of semiconductor chip in accordance with this invention.

FIG. 9 shows a cross-section view of one alternative embodiment of a step in processing of a semiconductor chip in accordance with this invention.

FIG. 10 shows a cross-section view of one alternative embodiment of a step in processing of a semiconductor chip in accordance with this invention.

FIG. 11 shows a cross-section view of one embodiment of a step in processing of semiconductor chip in accordance with this invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF EMBODIMENTS OF THE INVENTION

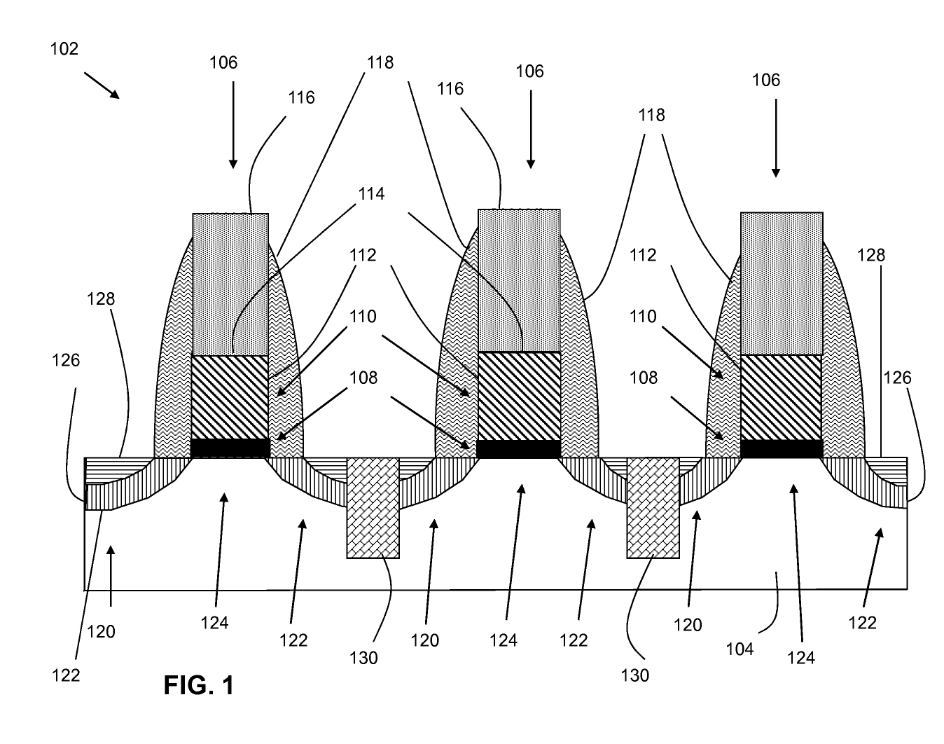

Referring to FIG. 1, a cross-section view of one embodiment of a step in processing of a semiconductor chip 102 in accordance with this invention is shown. Semiconductor chip 102 includes a substrate 104. A gate 106 may be formed over substrate 104 and may include a gate dielectric 108 over substrate 104 and a gate electrode 110 over gate dielectric 108. Gate dielectric 108 may be comprised of, for example, a silicon oxide and/or a hafnium oxide. Gate 106 may include a sidewall of gate 112 and a top surface of gate 114. Cap 116 may be formed over gate 106 and may include, for example, a nitride and/or an oxide. A spacer 118 may be formed adjacent to gate 106 and cap 116. A source 120 and a drain 122 may be formed in the substrate 104 and a channel 124 may run between source 120 and drain 122 in substrate 104. A person skilled in the art will readily recognize that location of source 120 and drain 122 may be reversed. Each of source 120 and drain 122 include a doped diffusion region 126 and a silicide region 128. A shallow trench isolation 130 may be formed in substrate 104 to isolate adjacent source 120 of one gate 106 and drain 122 of another gate 106. As understood other structures have been omitted for clarity. The omitted structures may include any conventional interconnect components, passive devices, etc., and additional transistors as employed to make SRAMs, etc.

Substrate 104 may be comprised of but not limited to silicon, germanium, silicon germanium, silicon carbide, and those consisting essentially of one or more Group III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Substrate 104 may also be comprised of Group II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). The processes to provide substrate 104, as illustrated and described, are well known in the art and thus, no further description is necessary.

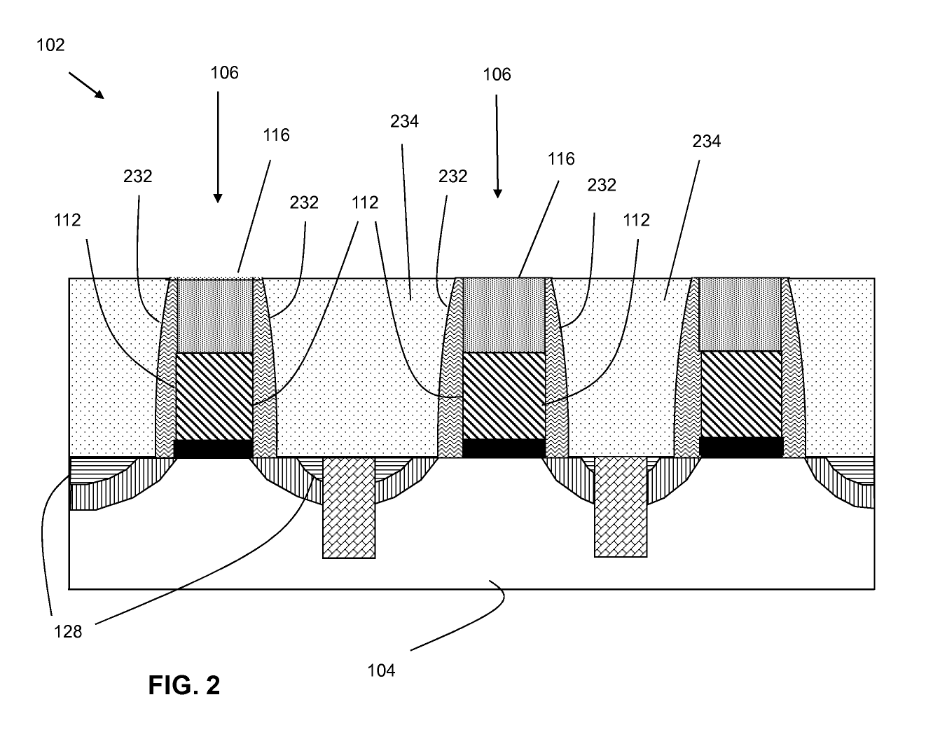

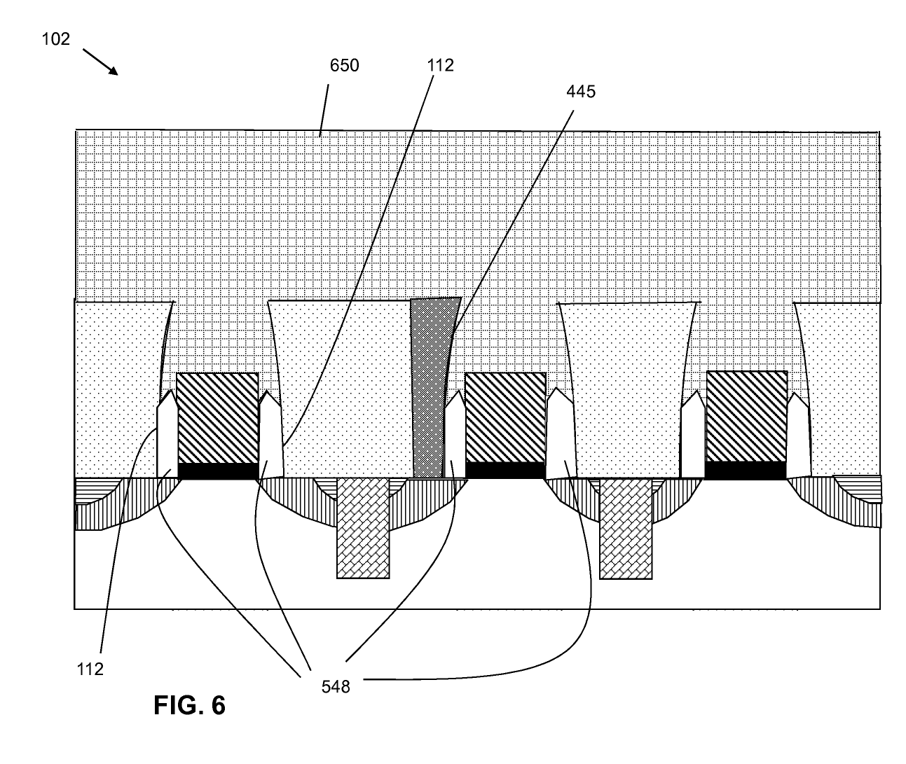

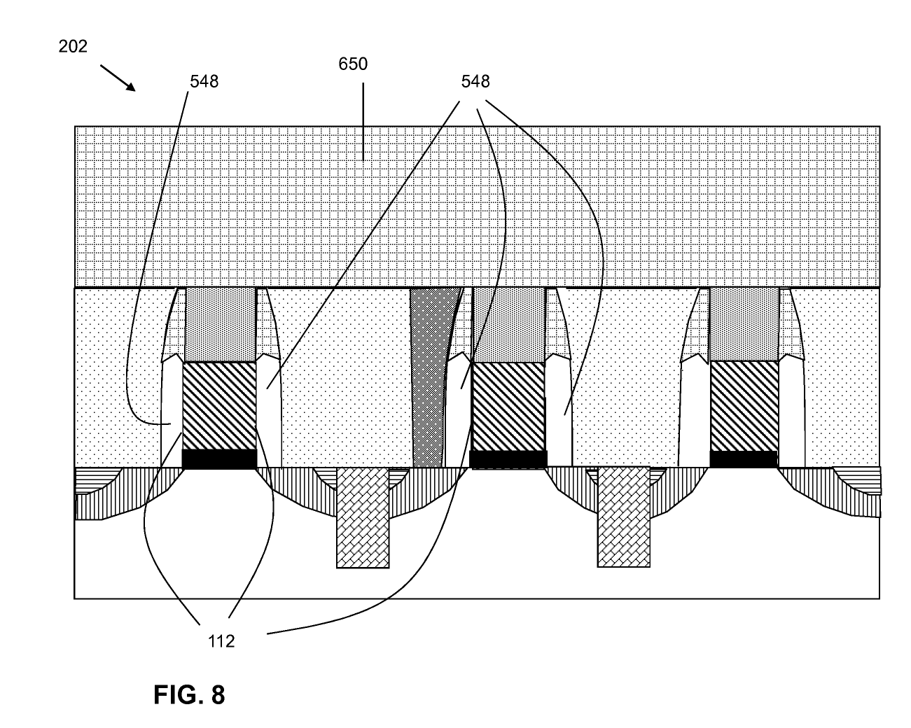

Referring to FIG. 2, a cross-section view of one embodiment of a step in processing of semiconductor chip 102 in accordance with this invention is shown. FIG. 2 shows forming a sacrificial spacer 232 adjacent to sidewall of gate 112. Sacrificial spacer 232 may be formed by removing spacer 118 (FIG. 1) and re-forming sacrificial spacer 232, e.g., by depositing a silicon nitride and performing a reactive ion etch (RIE). All or portion of spacer 118 may be used in re-forming sacrificial spacer 232. FIG. 2 also shows forming a first dielectric layer 234 over substrate 104 about gate 106 and sacrificial spacer 232. As observed by comparing FIGS. 1 and 2, sacrificial spacer 232 may be narrower than spacer 118 (FIG. 1) and may allow first dielectric layer 234 to protect silicide region 128 during subsequent sacrificial spacer 232 removal (see FIGS. 6 and 8). Sacrificial spacer 232 may separate sidewall of gate 112 from first dielectric layer 234. Planarization of first dielectric layer 234 by any known or to be developed method may expose cap 116 and sacrificial spacer 232.

First dielectric layer 234 may include silicon oxide (SiO₂), silicon nitride (SiN), or any other suitable material. Any number of dielectric layers may be located over the chip body, as may other layers included in semiconductor chips now known or later developed. In one embodiment, first dielectric layer 234 may include silicon oxide (SiO₂) for its insulating, mechanical and optical qualities. First dielectric layer 234 may include but is not limited to: silicon nitride (Si₃N₄), fluorinated SiO₂ (FSG), hydrogenated silicon oxycarbide (SiCOH), porous SiCOH, boro-phosho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available form JSR Corporation, other low dielectric constant (<3.9) material, or layers thereof. First dielectric layer 234 may be deposited using conventional techniques described herein and/or those known in the art.

As used herein, the term “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

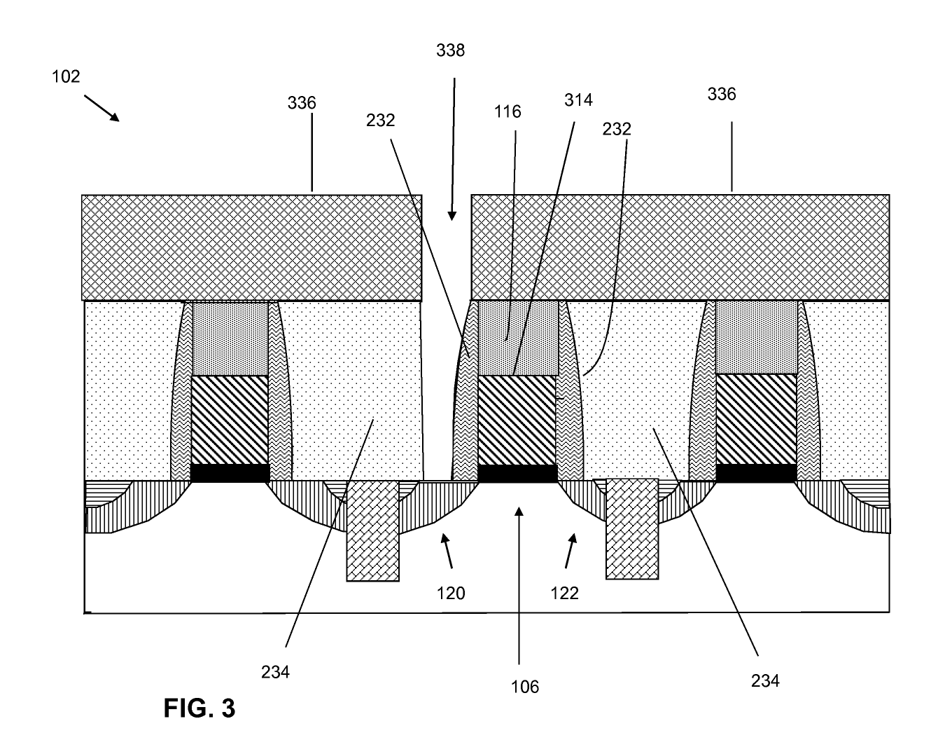

Referring to FIGS. 3-5, a cross sectional view of one embodiment of forming a contact to gate 106 is illustrated. In FIG. 3, a mask 336 may be formed over first dielectric layer 234. Forming mask 336 may include photoresist technique or any other known or to be developed techniques. An etching through first dielectric layer 234 and about sacrificial spacer 232 may form a contact channel 338 to source 120 or drain 122. Etching may exclude etching through a portion of sacrificial spacer 232. Contact channel 338 may be tapered, the tapering being a narrowing of contact channel 338 as the contact channel 338 nears source 120 or drain 122. Etching may include a chemical selective to photoresist.

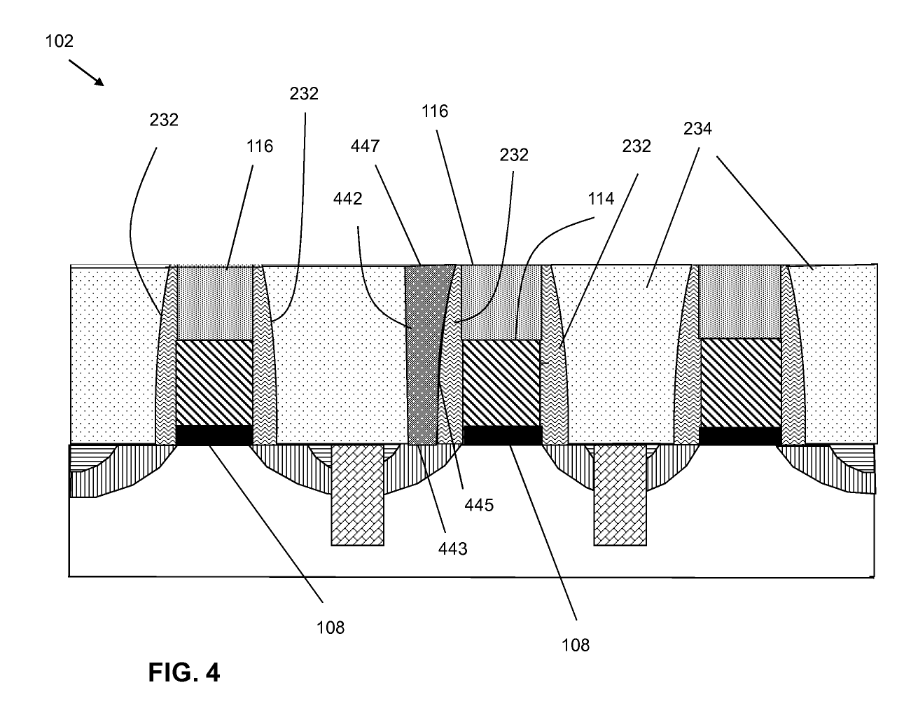

In FIG. 4, mask 336 (FIG. 3) may be removed using any known or to be developed technique. A tapered contact 442 may be formed in contact channel 338 (FIG. 3). Tapered contact 442 may include at least one of copper and tungsten. A first side 443 of tapered contact 442 may contact a portion of source 120 or drain 122. A second side 445 of tapered contact 442 may be formed about sacrificial spacer 232, and a third side 447 of tapered contact 442 may be opposite first side 443. Third side 447 may be wider than first side 443. Third side 447 may extend towards cap 116 and gate 106. Tapered contact 442 may be arched about sacrificial spacer 232. A liner material (not shown) as known in the art may be employed, if necessary.

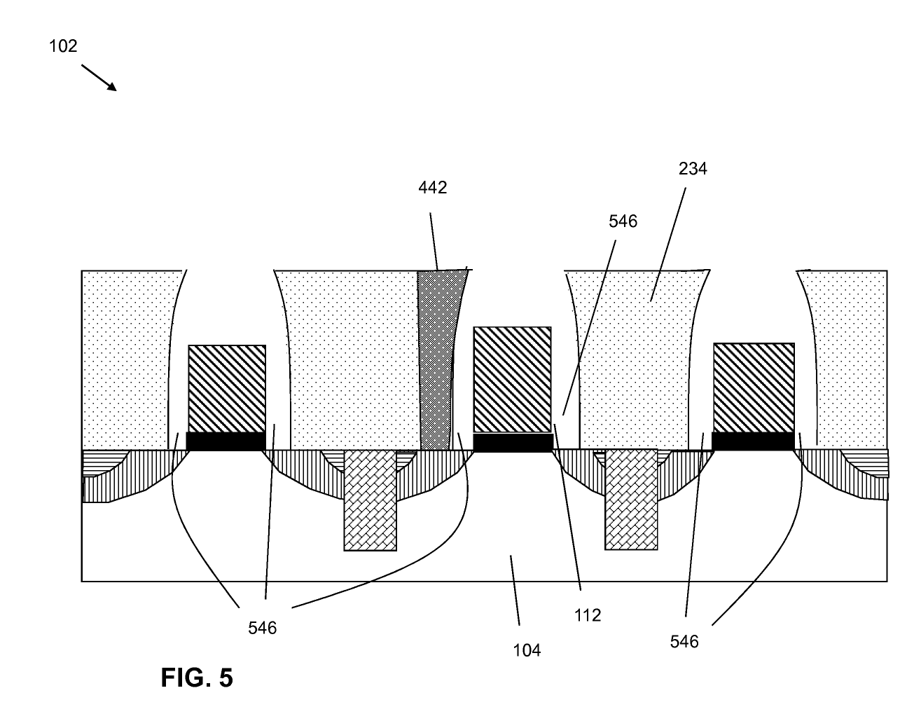

Referring to FIG. 5, substantially removing sacrificial spacer 232 (FIG. 4) and cap 116 (FIG. 4) leaving tapered contact 442 still there is illustrated. Space 546 over substrate 104 may be formed between sidewall of gate 112 and tapered contact 442. Alternatively, space 546 over substrate 104 may be formed between sidewall of gate 112 and first dielectric layer 234.

Referring again to FIG. 4, substantially removing sacrificial spacer 232 and cap 116 may include using a hot phosphorous wet etch. Hot phosphorous wet etch may be used, for example, when gate dielectric 108 includes an oxide, cap 116 includes a silicon nitride, sacrificial spacer 232 includes nitride and first dielectric layer 234 includes silicon oxide or low k film containing Si, C, O, and H (also known as carbon-doped oxide (CDO)). Alternatively, a hot phosphorous wet etch may be used, for example, when gate dielectric 108 includes hafnium oxide, cap 116 includes nitride, sacrificial spacer 232 includes hydrogenated nitride (SiNₓH_{y} silicon nitride having a high Si—N—H bond content) and first dielectric layer 234 includes carbon-doped oxide (CDO). Alternatively, substantially removing sacrificial spacer 232 and cap 116 may include using a buffered hydrofluoric acid wet etch. Buffered hydrofluoric acid wet etch may be used, for example, when gate dielectric 108 includes hafnium oxide, cap 116 includes oxide, sacrificial spacer 232 includes oxide and first dielectric layer 234 includes CDO. Alternatively, buffered hydrofluoric acid wet etch may be used, for example, when gate dielectric 108 includes hafnium oxide, cap 116 includes nitride, sacrificial spacer 232 includes oxide and first dielectric layer 234 includes CDO.

Referring to FIG. 6, forming sealed air gap 548 in the space by depositing a second dielectric layer 650 over first dielectric layer 234 is illustrated. Second dielectric layer 650 may partially fill space 546 (FIG. 5) and may create sealed air gap 548 adjacent to sidewall of gate 112. Sealed air gap 548 may form under a portion of second side 445 of tapered contact 442.

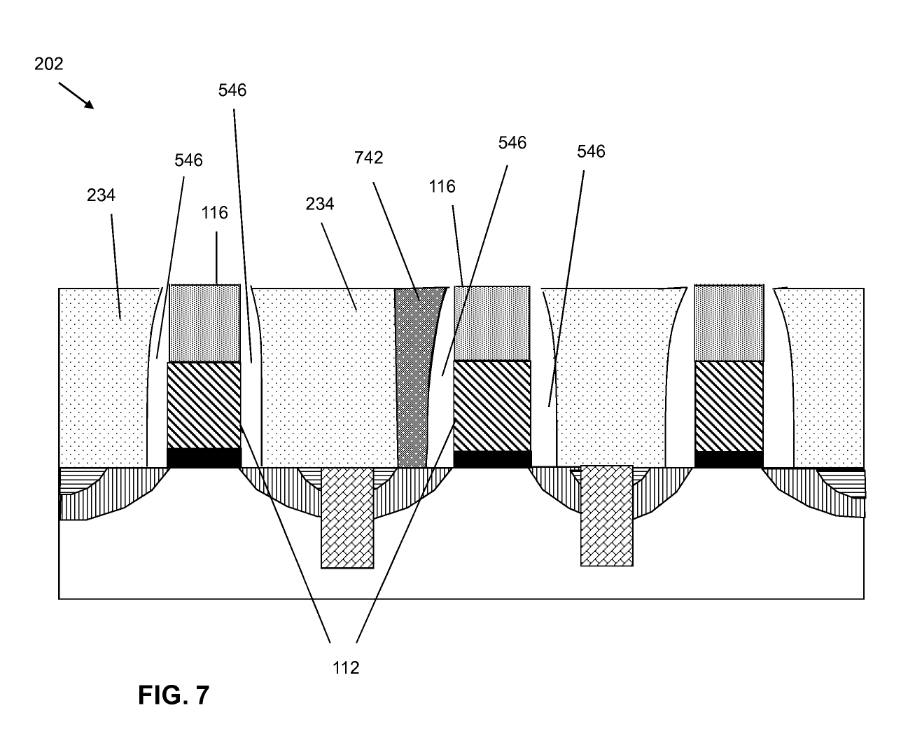

Referring to FIG. 7, a cross sectional view of one alternative embodiment of a step in forming a semiconductor chip 202 in accordance with this invention is shown. As applied to FIG. 5, sacrificial spacer 232 (FIG. 4) may be removed and cap 116 may remain intact exposing space 546 between sidewall of gate 112 and first dielectric layer 234. This process may include using, for example, a buffered hydrofluoric acid wet etch. Buffered hydrofluoric acid wet etch may be used, for example, when gate dielectric 108 includes hafnium oxide, cap 116 includes nitride, sacrificial spacer 232 includes hydrogenated nitride and first dielectric layer 234 includes CDO.

Referring to FIG. 8, a cross-section view of the alternative embodiment of FIG. 7 removing sacrificial spacer 232 with cap 116 remaining intact is illustrated. Second dielectric layer 650 may partially fill space 546 (FIG. 7) and may create sealed air gap 548 adjacent to sidewall of gate 112.

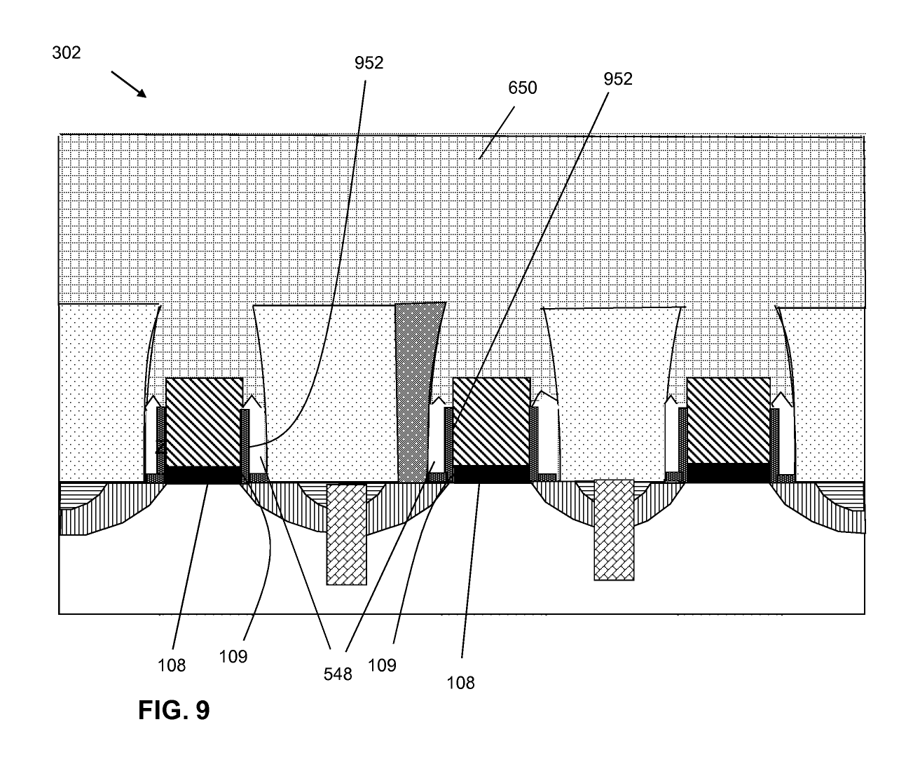

Referring to FIG. 9, a cross sectional view of one alternative embodiment of a step in forming a semiconductor chip 302 in accordance with this invention is shown. As applied to FIGS. 2-6, a dielectric barrier 952 may be formed substantially over a sidewall of gate dielectric 109 prior to forming sacrificial spacer 232 (FIG. 2). Dielectric barrier 952 may substantially prevent oxygen from diffusing into gate dielectric 108 during removal of sacrificial spacer 932 when using, for example, a buffered hydrogen fluoride wet etch. Dielectric barrier 952 may remain in sealed air gap 548 after forming second dielectric layer 650.

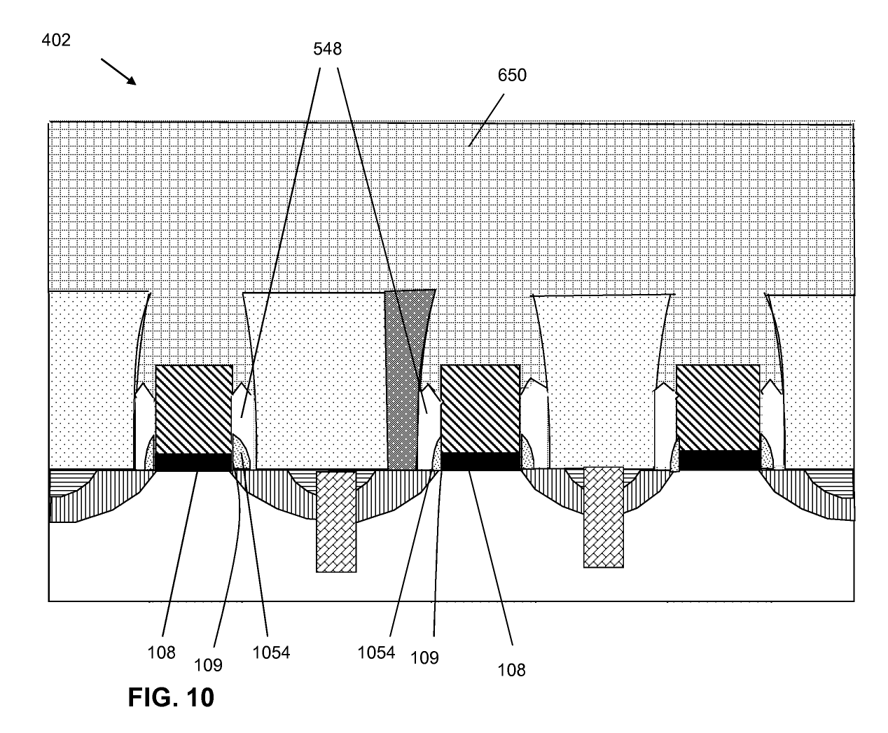

Referring to FIG. 10, a cross sectional view of one alternative embodiment of a step in forming a semiconductor chip 402 in accordance with this invention is shown. As applied to FIGS. 2-6, a protective spacer 1054 may be formed substantially over the sidewall of gate dielectric 109 prior to forming sacrificial spacer 232 (FIG. 2). Protective spacer 1054 may substantially prevent oxygen from diffusing into gate dielectric 108 during removal of sacrificial spacer 932 when using, for example, a buffered hydrogen fluoride wet etch. Protective spacer 1054 may remain in sealed air gap 548 after forming second dielectric layer 650.

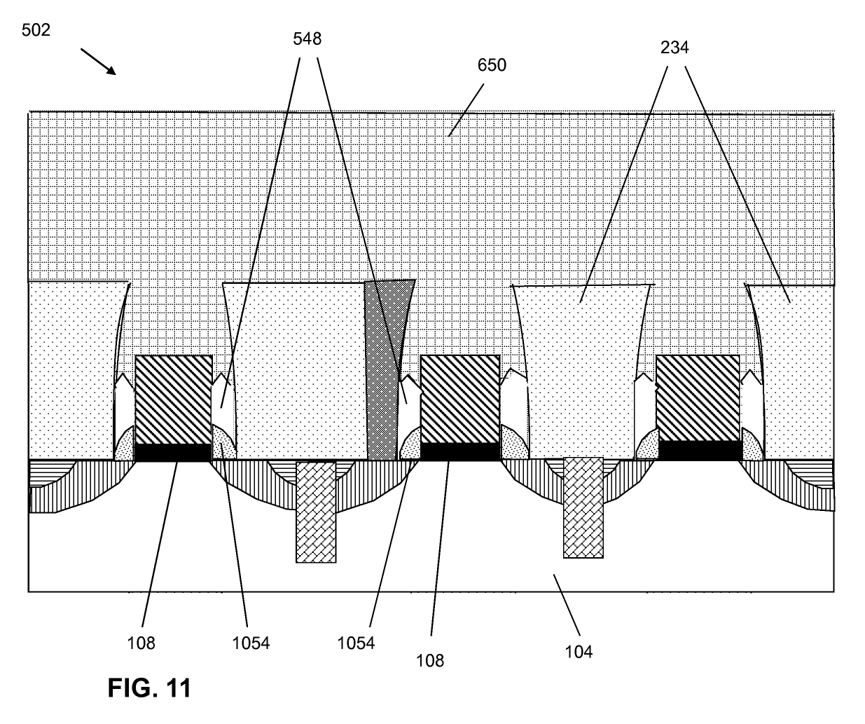

Referring to FIG. 11, a cross sectional view of one alternative embodiment of a step in forming a semiconductor chip 502 as applied to FIG. 10. Protective spacer 1054 may be formed with sufficient width to substantially span the substrate 104 exposed by space 546 (FIG. 5) between first dielectric layer 234 and gate 106. Substantially covering substrate 104 between first dielectric layer 234 and gate 106 may prevent damage to gate 106 when sacrificial spacer 232 is removed (FIG. 5) and may prevent damage to substrate 104 exposed by space 546 (FIG. 5) between first dielectric layer 234 and gate 106. As shown in FIG. 11 protective spacer 1054 may remain in sealed air gap 548 after forming second dielectric layer 650.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A semiconductor chip, comprising:
a substrate;
a first dielectric layer over the substrate;
a gate within the first dielectric layer, the gate including a sidewall;
a source and a drain in the substrate adjacent to the gate;
a tapered contact contacting a portion of one of the source or the drain; and
a sealed air gap between the sidewall, the tapered contact and a second dielectric layer, wherein the second dielectric layer partially fills a space between the tapered contact and the gate, and wherein the second dielectric layer directly contacts and covers a top side of the gate.

2. The chip of claim 1, wherein the tapered contact includes a first side contacting a portion of one of the source or the drain, a second side about the sacrificial spacer, and a third side opposite from and wider than the first side.

3. The chip of claim 1, further comprising a dielectric barrier within the sealed air gap and substantially over a sidewall of gate dielectric and the source and the drain in the substrate adjacent to the gate.

4. The chip of claim 1, further comprising a protective spacer over the sidewall of gate dielectric.

5. The chip of claim 1, wherein the tapered contact comprises at least one of copper and tungsten.

6. The chip of claim 1, further comprising a shallow trench isolation adjacent to the gate in the substrate.

7. A method, comprising:
forming a gate over a substrate;
forming a source and a drain in the substrate and adjacent to the gate;
forming a sacrificial spacer adjacent to the gate;
forming a first dielectric layer about the gate and the sacrificial spacer;
forming a tapered contact through the first dielectric layer and about the sacrificial spacer to one of the source or the drain;
substantially removing the sacrificial spacer, wherein a space is formed between the gate and the tapered contact; and
forming a sealed air gap in the space by depositing a second dielectric layer over the first dielectric layer, wherein the second dielectric layer partially fills a space between the tapered contact and the gate, and wherein the second dielectric layer directly contacts and covers a top side of the gate.

8. The method of claim 7, wherein the gate includes a gate dielectric; and
further comprising: forming a dielectric barrier substantially over a sidewall of gate dielectric and the source and the drain in the substrate prior to the sacrificial spacer forming.

9. The method of claim 7, wherein the gate includes a gate dielectric; and
further comprising prior to the sacrificial spacer forming: forming a protective spacer adjacent to the gate and adjacent to the gate dielectric;
removing a portion of the protective spacer; and
wherein the sacrificial spacer forming includes positioning the sacrificial spacer adjacent to the gate and over the protective spacer.

10. The method of claim 7, wherein the tapered contact comprises at least one of copper and tungsten.

11. The method of claim 7, further comprising:
forming a cap over the gate, the gate including a gate dielectric,
wherein the gate dielectric includes an oxide, the cap includes a nitride, the sacrificial spacer includes a nitride and the dielectric layer includes a carbon-doped oxide, and
wherein the substantially removing the sacrificial spacer includes using a hot phosphorous wet etch.

12. The method of claim 7, further comprising:
forming a cap over the gate, the gate including a gate dielectric,
wherein the gate dielectric includes a hafnium oxide, the cap includes an oxide, the sacrificial spacer includes an oxide and the dielectric layer includes a carbon-doped oxide, and
wherein the substantially removing the sacrificial spacer includes using a buffered hydrofluoric acid wet etch.

13. The method of claim 7, further comprising:
forming a cap over the gate, the gate including a gate dielectric,
wherein the gate dielectric includes a hafnium oxide, the cap includes an oxide, the sacrificial spacer includes a hydrogen nitride and the dielectric layer includes a carbon-doped oxide, and
wherein the substantially removing the sacrificial spacer includes using a buffered hydrofluoric acid wet etch.

14. The method of claim 7, further comprising:
forming a cap over the gate, the gate including a gate dielectric,
wherein the gate dielectric includes a hafnium oxide, the cap includes an nitride, the sacrificial spacer includes a hydrogen nitride and the dielectric layer includes a carbon-doped oxide, and
wherein the substantially removing the sacrificial spacer includes using a buffered hydrofluoric acid wet etch.

15. The method of claim 7, further comprising:
forming a cap over the gate, the gate including a gate dielectric,
wherein the gate dielectric includes a hafnium oxide, the cap includes a nitride, the sacrificial spacer includes a hydrogen nitride and the dielectric layer includes a carbon-doped oxide, and
wherein the substantially removing the sacrificial spacer includes using a hot phosphorous wet etch.

16. A method, comprising:
forming a gate over a substrate;
forming a source and a drain in the substrate adjacent to the gate;
forming a sacrificial spacer adjacent to a sidewall of the gate;
forming a first dielectric layer about the gate and the sacrificial spacer;
forming a tapered contact through the first dielectric layer and about the sacrificial spacer, wherein the tapered contact includes a first side contacting a portion of one of the source or the drain, a second side about the sacrificial spacer, and a third side opposite from and wider than the first side;
substantially removing the sacrificial spacer to form a space between the gate and the tapered contact; and
forming a sealed air gap in the space by depositing a second dielectric layer over the first dielectric layer, wherein the second dielectric layer partially fills a space between the tapered contact and the gate, and wherein the second dielectric layer directly contacts and covers a top side of the gate.

17. The method of claim 16, wherein the gate includes a gate electrode and a gate dielectric.

18. The method of claim 17, further comprising: forming a dielectric barrier substantially over a sidewall of gate dielectric prior to the sacrificial spacer forming.

19. The method of claim 17, further comprising prior to the sacrificial spacer forming:
forming a protective spacer adjacent to the gate and adjacent to the gate dielectric;
removing a portion of the protective spacer; and
wherein the sacrificial spacer forming includes positioning the sacrificial spacer adjacent to the gate and over the protective spacer.

20. The method of claim 16, wherein the tapered contact comprises at least one of copper and tungsten.
